(19) United States
(12) Patent Application Publication
(10) Pub. No.: US 2011/0065029 A1
(43) Pub. Date: Mar. 17, 2011

(54) Method of manufacturing mask structure

(76) Inventors: Hwan-Seok Seo, Suwon-si (KR); Byoung-Sup Ahn, Seongnam-si (KR); Dong-Gun Lee, Hwaseong-si (KR)

(21) Appl. No.: 12/882,652

(22) Filed: Sep. 15, 2010

(30) Foreign Application Priority Data
Sep. 16, 2009 (KR) 10-2009-0087491

(51) Int. Cl. G03F 1/00

(52) U.S. Cl. 430/5

(57) ABSTRACT

A method of forming a mask structure for an extreme ultraviolet ray lithography (EUVL) process includes defining a substrate including a first area and a second area, such that the first area has a pattern structure configured to selectively transmit light for the EUVL process and the second area encloses the first area, forming a reflection layer on the substrate, the reflection layer including alternately stacked molybdenum layers and silicon layers on the substrate, forming a capping layer on the reflection layer, forming an absorption pattern on the capping layer, the absorption pattern including a central portion corresponding to the first area of the substrate and a peripheral portion corresponding to the second area of the substrate, and forming a blind layer on the peripheral portion of the absorption pattern.

### BACKGROUND

1. Field

Example embodiments relate to a mask structure and a method of manufacturing the same, and more particularly, to a photo mask structure for an extreme ultraviolet lithography (EUVL) process and a method of manufacturing the same.

2. Description of the Related Art

High integration degree of semiconductor devices requires fine patterns. Since each device is required to be integrated in an extremely small area of a wafer, the size of each device decreases as much as possible, and thus, a pitch of the pattern in the device is designed to be as small as possible. That is, the pitch of the pattern of the semiconductor device, i.e., a sum of a width and an interval of the pattern, is required to be downsized so as to increase the integration degree of the semiconductor device.

In accordance with the above, the fine pattern in the semiconductor device may be formed by an extreme ultraviolet lithography (EUVL) process, in which extreme ultraviolet rays having an extremely short wavelength are used as a light source. For example, the extreme ultraviolet ray usually has a short wavelength of about 13.5 nm.

The EUVL process includes use of a mask pattern for transcribing an electronic pattern into a wafer. The mask pattern, however, has a reflective structure, as opposed to a transmitting structure, since the extreme ultraviolet ray usually has a short wavelength. That is, the extreme ultraviolet ray is reflected from a reflection layer in the mask pattern, i.e., about fifty bi-layers of molybdenum (Mo) layers and silicon (Si) layers alternately stacked and each having a thickness of about 7 nm, toward the wafer.

In detail, a conventional mask pattern for the EUVL process may include a light reflection layer and a light absorption pattern stacked on a substrate. The light reflection layer may be partially exposed through the light absorption pattern, i.e., the light absorption pattern may be patterned in accordance with the electronic pattern that is to be transcribed onto the wafer, so the layout of the absorption pattern may be transcribed onto the wafer as the electronic pattern of the semiconductor device.

However, as the absorption pattern is between the reflection layer and the wafer and has a predetermined thickness, a shadow effect may occur. That is, as the extreme ultraviolet rays are irradiated onto the wafer at an incident angle with respect to a top portion of the mask pattern, i.e., not perpendicularly, the rays reflected from the reflection layer may be partially covered with the absorption pattern, which protrudes from the reflection layer, thereby causing a shadow effect.

### SUMMARY

Embodiments are therefore directed to a photo mask structure for an EUVL process and a method of manufacturing the same, which substantially overcome one or more of the problems due to the limitations and disadvantages of the related art.

It is therefore a feature of an embodiment to provide a method of forming a mask structure for an EUVL process having a blind layer for shielding neighboring light from an adjacent shot, thereby reducing CD variation during a double exposure in an EUVL process and improving transcription quality thereof.

It is therefore another feature of an embodiment to provide a mask structure for an EUVL process of which the CD variation during a double exposure in an EUVL process is reduced to thereby improve transcription quality.

At least one of the above and other features and advantages may be realized by providing a method of forming a mask pattern for an EUVL process, including defining a substrate including a first area and a second area, such that the first area has a pattern structure configured to selectively transmit light for the EUVL process and the second area encloses the first area, forming a reflection layer on the substrate, the reflection layer including alternately stacked molybdenum layers and silicon layers on the substrate, forming a capping layer on the reflection layer, forming an absorption pattern on the capping layer, the absorption pattern including a central portion corresponding to the first area of the substrate and a peripheral portion corresponding to the second area of the substrate, and forming a blind layer on the peripheral portion of the absorption pattern.

Forming the capping layer may include forming at least one of a ruthenium layer and a silicon layer.

Forming the absorption pattern may include forming a low reflectivity tantalum boron nitride layer or a tantalum nitride layer.

The method may further include forming a photosensitive pattern on the central portion of the absorption pattern, forming the blind layer on the photosensitive pattern and the peripheral portion of the absorption pattern, and sequentially removing the blind layer and the photosensitive pattern from the first area of the substrate, such that the blind layer remains only on the peripheral portion of the absorption pattern.

Forming the blind layer may include pre-cleaning the peripheral portion of the absorption pattern by an ion beam etching process, and depositing a light-shielding material onto surfaces of the photosensitive pattern and the peripheral portion of the absorption pattern by an ion beam deposition process.

Depositing the light-shielding material may include depositing at least one of chromium, tantalum nitride, and tantalum boron nitride.

The pre-cleaning and depositing steps may be performed in-situ with each other in a same process chamber.

The ion beam etching process for the pre-cleaning may be performed by ion beams of oxygen gas, argon gas, and/or nitrogen gas.

Removing the blind layer and the photosensitive pattern may be performed by a lift-off process.

At least one of the above and other features and advantages may also be realized by providing a method of forming a mask structure for an EUVL process, including forming a reflection layer on a substrate, the substrate including a first area having a pattern structure configured to selectively transmit light for the EUVL process and a second area enclosing the first area, forming a capping layer on the reflection layer, forming an absorption pattern on the capping layer, the absorption pattern including a central portion corresponding to the first area of the substrate, the central portion including a gap space partially exposing the capping layer in the first area of the substrate, and a peripheral portion corresponding to the second area of the substrate and covering the capping layer in the second area of the substrate, forming a sacrificial pattern filling in the gap space of the central portion of the absorption pattern, forming a blind layer on the sacrificial pattern and the absorption pattern, partially removing the blind layer from the first area of the substrate, such that the central portion of the absorption pattern and the sacrificial pattern are exposed, and removing the sacrificial pattern from the first area of the substrate, such that the blind layer remains on the peripheral portion of the absorption pattern.

Forming the reflection layer may include alternately stacking molybdenum layers and silicon layers on the substrate.

Forming the capping layer may include forming at least one of a ruthenium layer and a silicon layer.

Forming the absorption pattern may include forming a low reflectivity tantalum boron nitride layer or a tantalum nitride layer.

Forming the sacrificial pattern may include forming at least one of a photosensitive pattern, a polysilicon pattern, and an oxide pattern.

Forming the blind layer may include using a light-shielding material, the light-shielding material including at least one of chromium, tantalum nitride, and tantalum boron nitride.

Removing the blind layer may be performed by a dry etching process, and removing the sacrificial pattern may be performed by a wet etching process.

At least one of the above and other features and advantages may also be realized by providing a mask structure for an EUVL process, including a substrate including a first area and a second area, the first area having a pattern structure configured to selectively transmit light for the EUVL process, and the second area enclosing the first area, a reflection layer on the substrate, the reflection layer including alternately stacked molybdenum layers and silicon layers on the substrate, a capping layer on the reflection layer, an absorption pattern on the capping layer, the absorption pattern including a central portion corresponding to the first area of the substrate and a peripheral portion corresponding to the second area of the substrate, and a blind layer on the peripheral portion of the absorption pattern.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates electron microscopic photographs of pattern printability according to different thicknesses of corresponding absorption patterns and multiple exposures of neighboring shots;

FIG. 2 illustrates a graph of CD variations in accordance with the thickness of the absorption pattern, the double exposure, and the optical density;

FIG. 3 illustrates a plan view of a mask pattern for an EUVL process in accordance with a first example embodiment of the present inventive concept;

FIG. 4 illustrates a graph of reflectivity and optical density in different regions of the mask structure of FIG. 3;

FIGS. 5 to 11 illustrate cross-sectional views of processing steps for a method of foaming an EUVL mask structure in accordance with an example embodiment of the present inventive concept;

FIGS. 12 to 18 illustrate cross-sectional views of processing steps for a method of forming an EUVL mask structure in accordance with another example embodiment of the present inventive concept;

FIG. 19 illustrates a view of a structure of an ion beam deposition (IBD) apparatus at a pre-cleaning mode; and

FIG. 20 illustrates a view of a structure of the IBD apparatus at a deposition mode.

### DETAILED DESCRIPTION

Korean Patent Application No. 10-2009-0087491, filed on Sep. 16, 2009, in the Korean Intellectual Property Office, and entitled: “Mask Structure and Method of Manufacturing the Same,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will be understood that when an element or layer is referred to as being “on,” “connected to,” “coupled to,” or “between” another element or layer, it can be directly on, connected, coupled, or between the other element or layer or intervening elements or layers may be present. In contrast, when an element is referred to as being “directly on,” “directly connected to,” “directly coupled to,” or “directly between” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

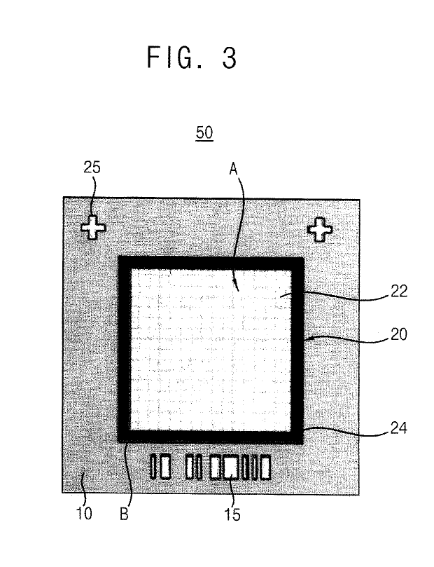

Hereinafter, an example embodiment of a mask structure will be explained in detail with reference to FIG. 3. FIG. 3 illustrates a plan view of a mask structure for an EUVL process in accordance with a first example embodiment of the present inventive concept.

Referring to FIG. 3, a mask structure 50 for an EUVL process (hereinafter, referred to as EUVL mask structure) may include a transparent substrate 10, e.g., quartz, a mask code 15, a pattern area 20, and an aligning key 25. The substrate 10 may include a central region and a peripheral region. In the present example embodiment, the transparent substrate 10 may be partially coated with an opaque material except for some portions at which the mask code 15, the pattern area 20, and the aligning key 25 are positioned.

For example, the pattern area 20 may include a first area A in which a pattern structure 22 for the EUVL process is arranged, and a second area B in which a blind layer 24 for shielding light is arranged. For example, the first area A may be enclosed by the second area B. Thus, the pattern structure 22 may be enclosed, e.g., completely surrounded along its perimeter, by the blind layer 24 in the pattern area 20.

During the EUVL process, the blind layer 24 may prevent light from passing through the second area B, thereby minimizing double exposure in the EUVL process and CD variation due to the double exposure. Accordingly, the transcription quality of the mask structure 50 may be substantially improved due to the minimization of the CD variation, as will be described in more detail below.

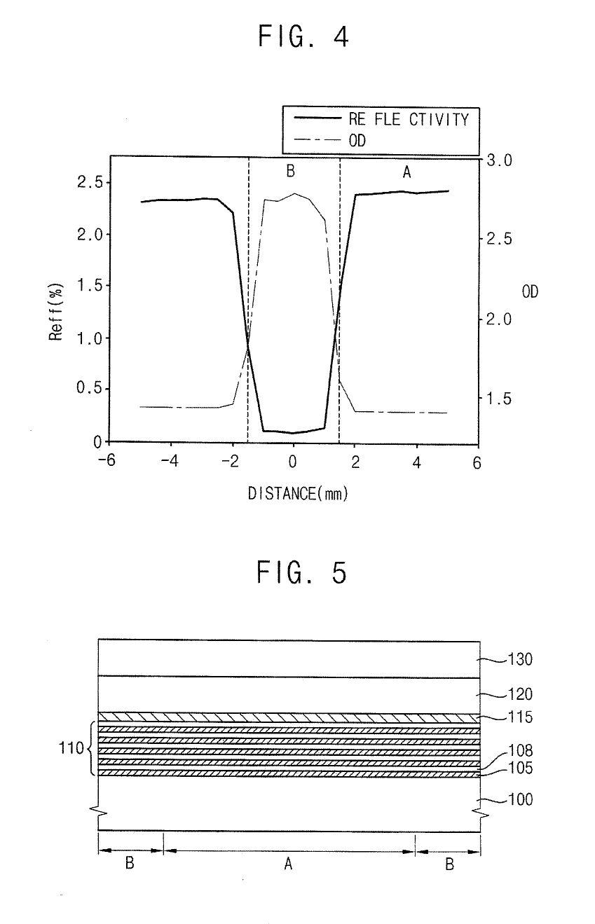

FIG. 4 illustrates a graph showing relations between reflectivity and optical density of extreme ultraviolet ray incident onto the mask structure 50 in FIG. 3. As illustrated in FIG. 4 by the solid line, the reflectivity of the extreme ultraviolet ray may be substantially lower in the second area B of the EUVL mask structure 50 than in the first area A due to the blind layer 24. Further, as illustrated in FIG. 4 by the dashed line, the optical density (OD) of the extreme ultraviolet ray may be substantially higher in the second area B of the EUVL mask structure 50 than in the first area A due to the blind layer 24.

Accordingly, as the blind layer 24 prevents light from passing through the second area B of the EUVL mask structure 50, the absorption layer of the EUVL mask structure 50 may be formed to a substantially small thickness without affecting double exposure. Therefore, the shadow effect may be minimized. In addition, the EUVL mask structure 50 including the blind layer 24 may have a sufficient optical density in the peripheral region, thereby preventing or substantially minimizing deterioration of the transcription quality caused by the double exposure.

FIGS. 5 to 11 illustrate cross-sectional views of processing steps in a method of forming an EUVL mask structure in accordance with an example embodiment.

Referring to FIG. 5, a transparent substrate 100 may be prepared for formation of the EUVL mask structure. For example, the transparent substrate 100 may include glass material, e.g., quartz. For example, as described previously with reference to substrate 10 in FIG. 3, the transparent substrate 100 may include a first area A in which a pattern structure for the EUVL is arranged, and a second area B in which the blind pattern for shielding light from a neighboring shot in an exposure process is arranged.

A reflection layer 110 may be formed on the substrate 100 by an ion beam deposition (IBD) process or an atomic layer deposition (ALD) process. For example, the reflection layer 110 may include a plurality of alternately stacked molybdenum (Mo) layers 105 and silicon layers (Si) 108 on the substrate 100. That is, the reflection layer 110 may include a bi-layer having the molybdenum layer (Mo) 105 and the silicon layer (Si) 108 on the substrate 100, and a number of the bi-layers may be provided as the reflection layer 110. In the present example embodiment, the reflection layer 110 may include about 40 to about 50 bi-layers that may be stacked on the substrate 100. In an example embodiment, extreme ultraviolet rays having a wavelength of about 13.5 nm may be reflected from the reflection layer 110.

A capping layer 115 may be formed on the reflection layer 110. The capping layer 115 may function as an etch stop layer in a subsequent etching process, and thus, the reflection layer 110 may be protected from being etched in the etching process. For example, the capping layer 115 may include a ruthenium (Ru) layer having a thickness of about 25 Å and/or a silicon (Si) layer having a thickness of about 110 Å.

An absorption layer 120 for absorbing light may be formed on the capping layer 115. The absorption layer 120 may include a central portion corresponding to the first area A of the substrate 100 and a peripheral portion corresponding to the second area B of the substrate 100. For example, the absorption layer 120 may include a tantalum boron nitride (TaBN) layer having low reflectivity (LR-TaBN) in view of high detection sensitivity. In place of the LR-TABN, a tantalum nitride (TaN) layer may be used as the absorption layer 120 in view of sufficient absorption of the extreme ultraviolet ray. Thereafter, a first photosensitive layer 130 may be formed on the absorption layer 120.

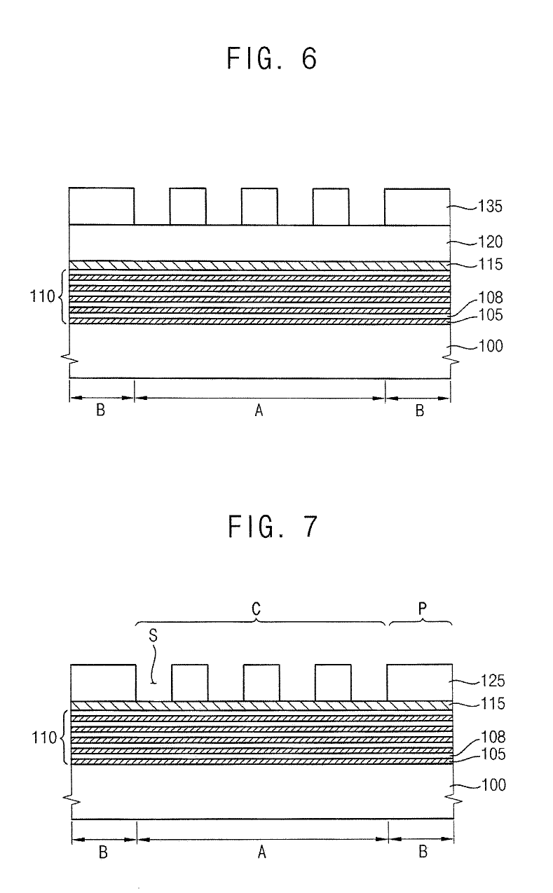

Referring to FIG. 6, the first photosensitive layer 130 may be patterned into a first photosensitive pattern 135 by an electron beam or by a photolithography process. In the present example embodiment, the first photosensitive pattern 135 may be formed by the electron beam to provide patterning accuracy.

Referring to FIG. 7, the absorption layer 120 may be formed into an absorption pattern 125 by an etching process using the first photosensitive pattern 135 as an etching mask. A reflected ray may be absorbed into the absorption pattern 125. The central portion of the absorption layer 120 may be patterned by the etching process, and the peripheral portion of the absorption layer 120 may remain unchanged. Therefore, the absorption pattern 125 may include a plurality of gap spaces S in its central portion C, so the capping layer 115 may be partially exposed through the gap spaces S in a region corresponding to the first area A of the substrate 100. A peripheral portion P of the absorption pattern 125 may remain unchanged. Further, the reflection layer 110 may remain substantially unchanged after the etching process, i.e., the process for forming the absorption pattern 125, due to the capping layer 115.

In the present example embodiment, the absorption pattern 125 may be formed via a single etching process without substantial loss of the capping layer 115. Thus, no damage may be caused to the absorption pattern 125 and the reflection layer 110, thereby minimizing transcription failures in an EUVL process using the mask structure 50.

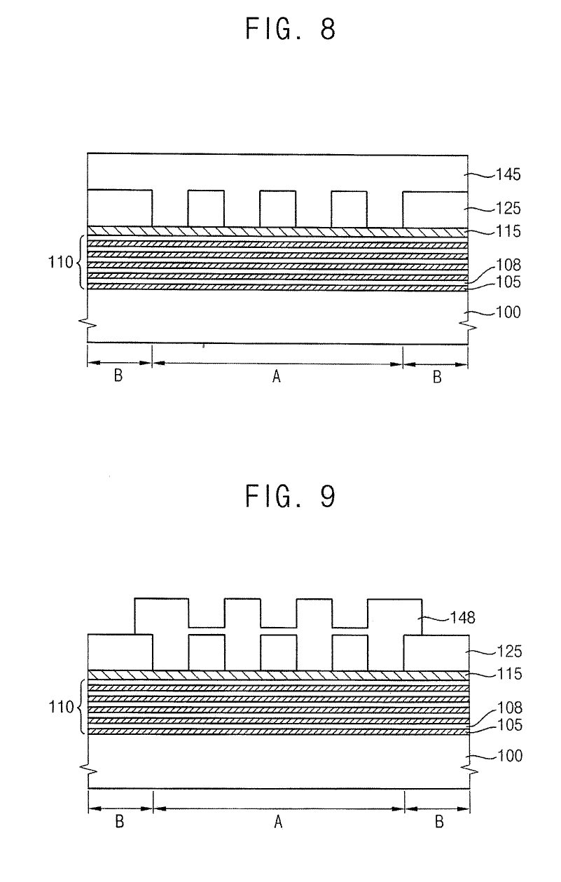

Referring to FIG. 8, a second photosensitive layer 145 may be formed on the absorption pattern 125 and the capping layer 115 by the same process as the first photosensitive layer 130. Thus, the gap spaces S of the absorption pattern 125 may be filled up with the second photosensitive layer 145. The second photosensitive layer 145 may have a flat surface by a planarization process. In the present example embodiment, the second photosensitive layer 145 may include the same material as the first photosensitive layer 130.

Referring to FIG. 9, the second photosensitive layer 145 may be patterned into a second photosensitive pattern 148 by electron beams or by a photolithography process in such a manner that the second photosensitive layer 145 on the first area A may be formed into the second photosensitive pattern 148, and the second photosensitive layer 145 on the second area B may be removed from the substrate 100. That is, the central portion of the absorption pattern 125 may be covered with the second photosensitive pattern 148, and the peripheral portion of the absorption pattern 125 may be exposed.

In the present example embodiment, the second photosensitive pattern 148 may be shaped into a series of protrusion portions and recessed portions in the first area A of the substrate 100 for facilitating a subsequent lift-off process. While the present example embodiment discloses a series of the protrusion portions and recessed portions in the first area A, any other modified shape may be used in the second photosensitive pattern 148 as long as the first area A is covered with and the second area B is revealed by the second photosensitive pattern 148.

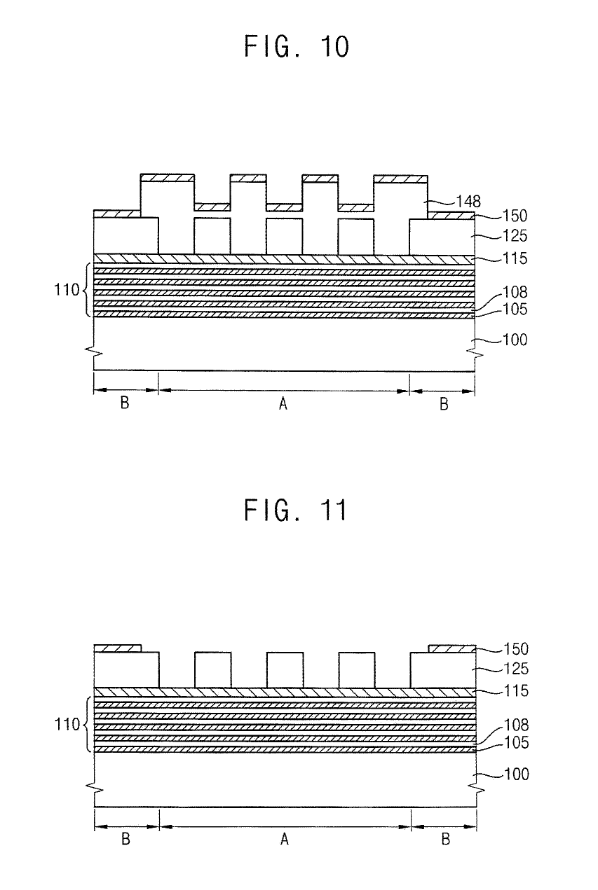

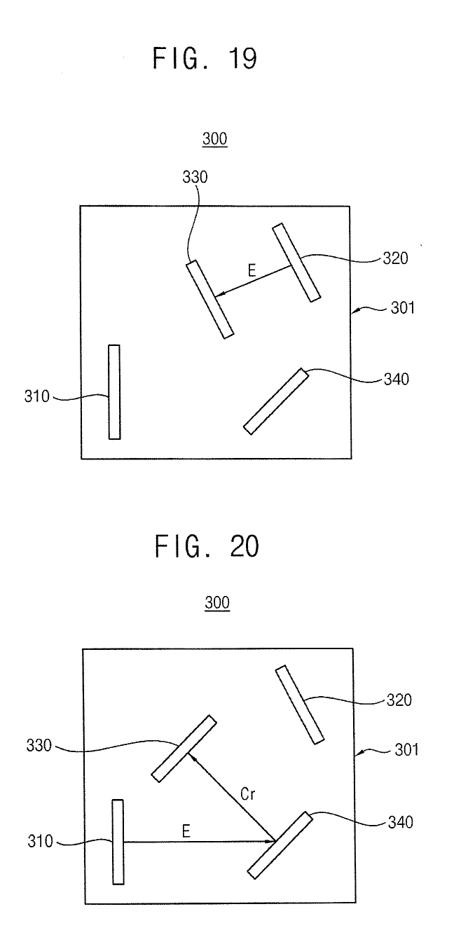

Referring to FIG. 10, a blind layer 150 may be formed on an entire surface of the substrate 100 including the first and second areas A and B by an ion beam deposition (IBD) process or a sputtering process. In the present example embodiment, the blind layer 150 may be formed on the substrate 100 by the IBD process, as described hereinafter with reference to FIGS. 19 and 20. That is, the blind layer 150 may be formed on the second photosensitive pattern 148, e.g., only on an upper surface of the second photosensitive pattern 148, and on the peripheral portion of the absorption pattern 125, e.g., only on an upper surface of the absorption pattern 125.

FIG. 19 illustrates a structure of an IBD apparatus at a pre-cleaning mode, and FIG. 20 illustrates a view of an IBD apparatus at a deposition mode. Referring to FIGS. 19 and 20, an IBD apparatus 300 includes a deposition power source 310 that is secured to a sidewall of a process chamber 301 at an angle of about 0°, and an etch power source 320 that is secured to the sidewall of the process chamber 301 at an angle of about 21° clockwise from a bottom of the process chamber 301.

A preliminary mask structure 330 including the absorption pattern 125 and the second photosensitive pattern 148 may be spaced apart from both of the deposition power source 310 and the etch power source 320 by a predetermined distance in the process chamber 301, and may be rotated through 360° with respect to a central axis thereof. Further, a target specimen 340 may be arranged in the process chamber 301 at an angle of about 35° counterclockwise from the bottom of the process chamber 301.

In operation of the IBD apparatus 300 at the pre-cleaning mode as illustrated in FIG. 19, the preliminary mask 330 may be arranged to face the etch power source 320 in the IBD apparatus 300, and ion beams may be injected onto the preliminary mask 330 from the etch power source 320. Thus, residuals of the photosensitive materials may be clearly removed from the surface of the peripheral portion of the absorption pattern 125 by the ion beams, thereby improving coherence quality of the blind layer to the second area B of the substrate 100. For example, the ion beam cleansing process may be performed using oxygen (O₂) gas, argon (Ar) gas, and nitrogen gas (N₂).

In operation of the IBD apparatus 300 at the deposition mode as illustrated in FIG. 20, the preliminary mask 330 may be changed to face the target specimen 340 in the IBD apparatus 300, and ion beams may be injected onto the target specimen 340 from the deposition power source 310. For example, light-shielding materials, e.g., chromium (Cr) particles, may be emitted from the target specimen 340 and be deposited onto the preliminary mask 330. That is, the particles of the light-shielding materials may be injected onto a surface of the second photosensitive pattern 148 and the absorption pattern 125 as ion beams.

In the present example embodiment, the pre-cleaning mode and the deposition mode may be performed in-situ with each other in the same process chamber of the IBD apparatus. Accordingly, referring back to FIG. 10, the blind layer 150 may be formed on a top surface of the peripheral portion of the absorption pattern 125 at the second area B and on top and bottom surfaces of the second photosensitive pattern 148 at the first area A of the substrate 100, as illustrated in FIG. 10. The blind layer 150 may include light-shielding materials, e.g., chromium (Cr), tantalum nitride (TaN), tantalum boron nitride (TaBN), etc.

Referring to FIG. 11, the second photosensitive pattern 148 and the blind layer 150 may be removed from the first area A of the substrate 100 by a lift-off etching process, e.g., using LAL as an etchant. Therefore, the EUVL mask structure shown in FIG. 3 may be formed, i.e., the blind layer 150 may remain only on the peripheral portion of the absorption pattern 125 in the second area B.

Thus, the pattern structure 22 in the EUVL mask structure 50 of FIG. 3 may be arranged in the first area A, i.e., the pattern defined by the absorption pattern 125, and may be enclosed by the blind layer 150 in the second area B like a fence surrounding the pattern structure 22. It is noted that the blind layer 150 in FIG. 11 may be substantially the same layer as the blind layer 24 in FIG. 3. As such, the blind layer 150 for shielding light may be formed in the second area B of the substrate 100, thereby minimizing the CD variation at the point of the double exposure and increasing the transcription quality. In addition, since the blind layer 150 is formed by the lift-off process, damage to the capping layer 115 may be prevented or substantially minimized, and the process for forming the mask structure 50 may be simplified.

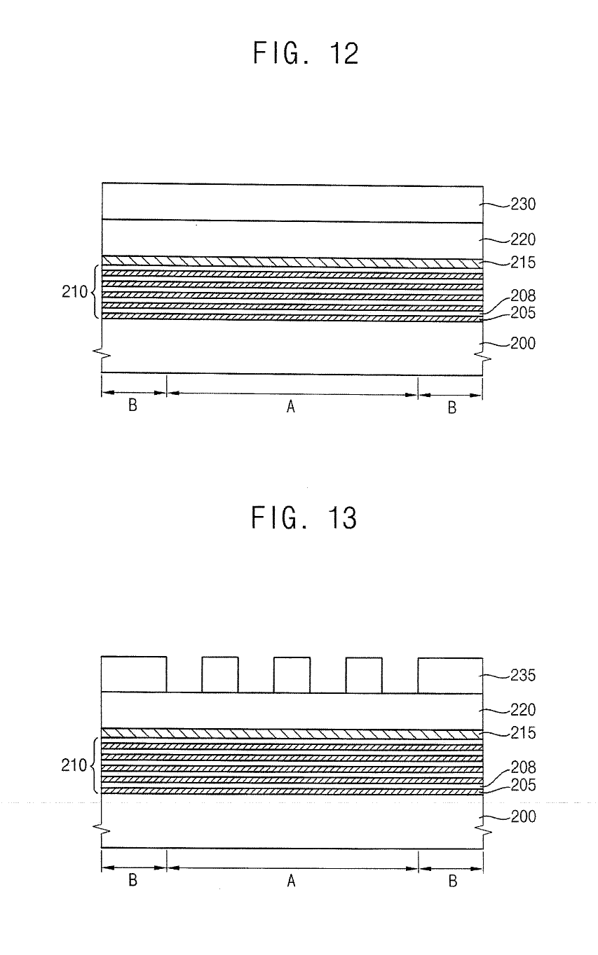

FIGS. 12 to 18 illustrate cross-sectional views of steps for a method of forming an EUVL mask structure in accordance with another example embodiment.

Referring to FIG. 12, a transparent substrate 200 may be prepared for formation of the EUVL mask structure. For example, the transparent substrate 200 may include glass material, e.g., quartz. For example, as described previously with reference to FIG. 3, the transparent substrate 200 may include a first area A in which a pattern structure for the EUVL is arranged and a second area B in which a blind pattern for shielding light from a neighboring shot in an exposure process is arranged.

A reflection layer 210 may be formed on the substrate 200 by an ALD process. For example, the reflection layer 210 may include a molybdenum (Mo) layer 205 and a silicon layer (Si) 208 that may be alternately stacked on the substrate 200. That is, the reflection layer 210 may include a bi-layer having the molybdenum layer (Mo) 205 and the silicon layer (Si) 208 and a number of the bi-layers may be provided as the reflection layer 210. In the present example embodiment, the reflection layer 210 may include about 40 to about 50 bi-layers that may be stacked on the substrate 200. In an example embodiment, extreme ultraviolet rays having a wavelength of about 13.5 nm may be reflected from the reflection layer 210.

A capping layer 215 may be formed on the reflection layer 210. The capping layer 215 may function as an etch stop layer in a subsequent etching process, and thus, the reflection layer 210 may be protected from being etched in the etching process. For example, the capping layer 215 may include a ruthenium (Ru) layer having a thickness of about 25 Å, and/or a silicon (Si) layer having a thickness of about 110 Å.

An absorption layer 220 for absorbing light may be formed on the capping layer 115, and thus, the absorption layer 220 may include a central portion corresponding to the first area A of the substrate 200 and a peripheral portion corresponding to the second area B of the substrate 200. For example, the absorption layer 220 may include a tantalum boron nitride (TaBN) layer having low reflectivity (LR-TaBN) in view of high detection sensitivity. In place of the LR-TABN, a tantalum nitride (TaN) layer may be used as the absorption layer 220 in view of sufficient absorption of the extreme ultraviolet ray. Thereafter, a first photosensitive layer 230 may be formed on the absorption layer 220.

Referring to FIG. 13, the first photosensitive layer 230 may be patterned into a first photosensitive pattern 235 by an electron beam or by a photolithography process. In the present example embodiment, the first photosensitive pattern 235 may be formed by the electron beam in view of patterning accuracy.

Referring to FIG. 14, the absorption layer 220 may be formed into an absorption pattern 225 by an etching process using the first photosensitive pattern 235 as an etching mask. Reflected rays may be absorbed into the absorption pattern 235. In the present example embodiment, the central portion of the absorption layer 220 may be partially etched off, and the peripheral portion of the absorption layer 220 may remain unchanged. Therefore, the absorption pattern 225 may have a plurality of gap spaces S through which the capping layer 215 may be partially exposed at the first area A of the substrate 200. The capping layer 215 may still be covered with the absorption pattern 225 at the second area B of the substrate 100. The capping layer 215 may remain substantially unchanged after the etching process for forming the absorption pattern 225.

In the present example embodiment, the absorption pattern 225 may be formed via a single etching process without substantial loss of the capping layer 215. Therefore, damage to the absorption pattern 225 and the reflection layer 210 may be prevented or substantially minimized, thereby reducing transcription failures in an EUVL process using the mask structure.

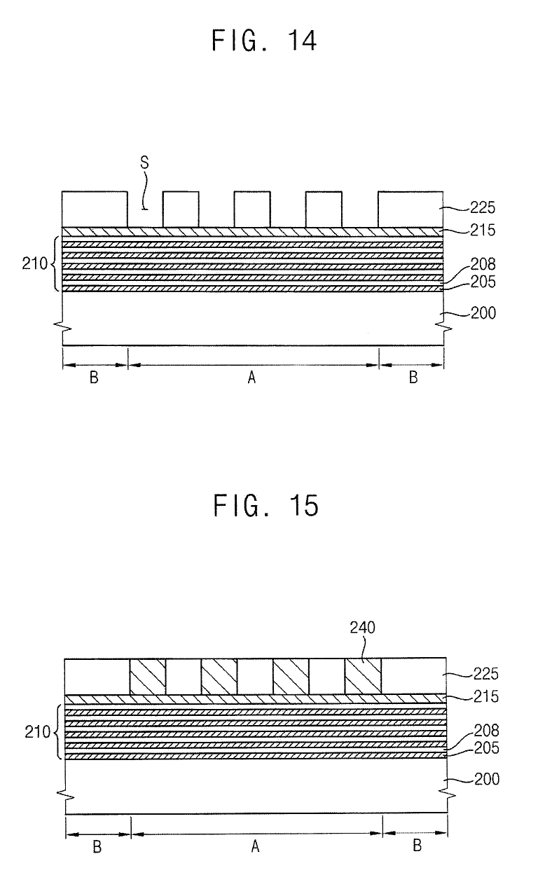

Referring to FIG. 15, a sacrificial layer (not shown) may be formed on the absorption pattern 225, and may be planarized until a top surface of the absorption pattern 225 is exposed. Therefore, the gap spaces S of the absorption pattern 225 may be filled with the sacrificial layer to form a sacrificial pattern 240 on the capping layer 215.

The sacrificial pattern 240 may include any materials that are different from both of the absorption pattern 225 and the capping layer 215 and may be easily removed from the capping layer 215 by an etching process. For example, the sacrificial pattern 240 may include silicon oxide and/or polysilicon, since the capping layer 215 and the absorption pattern 225 include metal. In the present example embodiment, the sacrificial pattern 240 may include a photosensitive materials in view of process simplification and convenience.

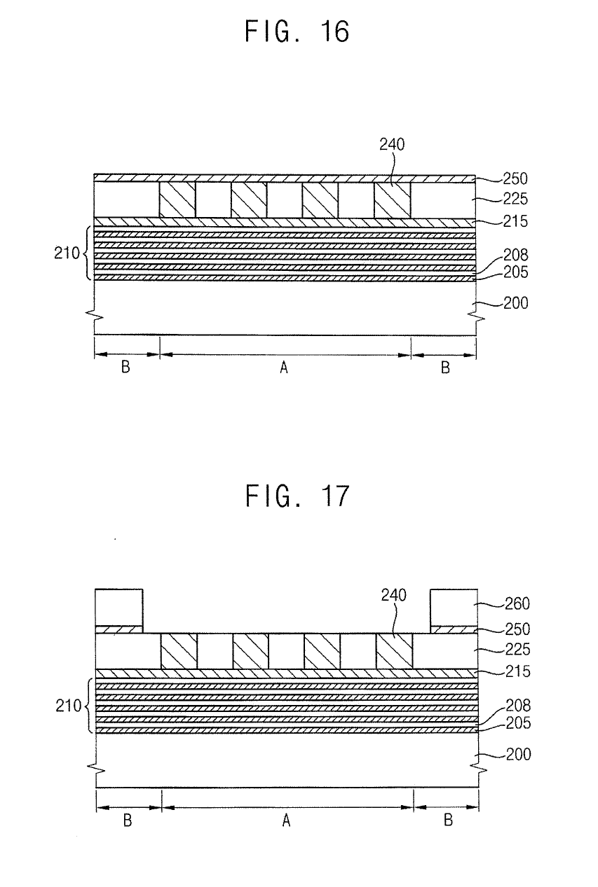

Referring to FIG. 16, a blind layer 250 may be formed on the absorption pattern 225 and the sacrificial pattern 240 by the same process as described with reference to FIGS. 19 and 20 in the IBD apparatus 300. In operation of the IBD apparatus 300 at the pre-cleaning mode, as illustrated in FIG. 19, the preliminary mask 330 including the absorption pattern 225 and the sacrificial pattern 240 may be arranged to face the etch power source 320 in the IBD apparatus 300, and ion beams may be injected onto the preliminary mask 330 from the etch power source 320. Thus, foreign matter, e.g., residuals of the photosensitive materials, may be clearly removed from surfaces of the absorption pattern 225 and the sacrificial pattern 240 by the ion beams. As such, the surfaces of the sacrificial pattern 240 and the absorption pattern 225 may be cleansed. In case the sacrificial pattern 240 includes photosensitive material, a top surface of the sacrificial pattern 240 may also be hardened in the pre-cleaning mode, thereby increasing coherence quality of the blind layer 250. For example, the ion beam cleansing process may be performed using oxygen (O₂) gas, argon (Ar) gas, and/or nitrogen gas (N₂).

In operation of the IBD apparatus 300 at the deposition mode, as illustrated in FIG. 20, the preliminary mask 330 may be changed to face the target specimen 340 in the IBD apparatus 300 and ion beams may be injected onto the target specimen 340 from the deposition power source 310. Thus, chromium (Cr) particles may be emitted from the target specimen 340 and be deposited onto the preliminary mask 330.

In the present example embodiment, the pre-cleaning mode and the deposition mode may be performed in-situ with each other in the same process chamber of the IBD apparatus. Accordingly, the blind layer 250 may be formed on top surfaces of the sacrificial pattern 240 and the absorption pattern 225, as shown in FIG. 16. The blind layer 250 may include light-shielding materials, e.g., at least one of chromium (Cr), tantalum nitride (TaN), and tantalum boron nitride (TaBN).

Referring to FIG. 17, a second mask pattern 260 may be formed on the blind layer 250 in such a manner that a first portion of the blind layer 250 corresponding to the first area A is exposed through the second mask pattern 260, and a second portion of the blind layer 250 corresponding to the second area B is covered with the second mask pattern 260. Then, the first portion of the blind layer 250 may be removed from the substrate 200 by a dry etching process using the second mask pattern 260 as an etching mask. Thus, the absorption pattern 225 and the sacrificial pattern 240 may be exposed only in the first area A of the substrate 200.

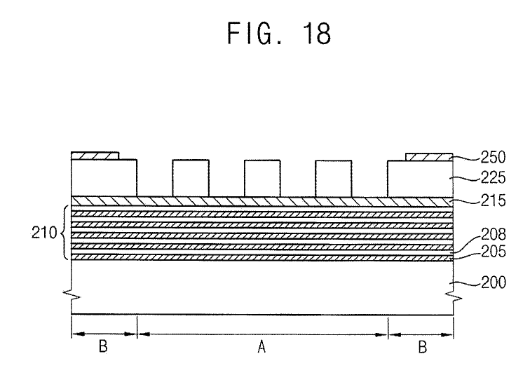

Referring to FIG. 18, the second mask pattern 260 may be removed from the substrate 200 by a strip process, and the sacrificial pattern 240 may also be removed from the substrate 200 by a wet etching process. Thus, the blind layer 250 may be formed only in the second area B of the substrate 200, and no blind layer may be arranged in the first area A of the substrate 100. Therefore, the EUVL mask structure 50 may be formed.

Thus, the mask pattern 22 in the EUVL mask structure 50 may be arranged in the first area A and may be enclosed by the blind layer 250, i.e., blind layer 24, that may be arranged in the second area B like a fence surrounding the pattern structure 22.

According to an example embodiment of the EUVL mask structure, the blind layer 250 for shielding light may be formed in the second area B of the substrate 200 to reduce CD variation at the point of the double exposure and to increase the transcription quality. In addition, since the blind layer 250 is formed by the lift-off process, damage to the capping layer 115 may be avoided and the process for forming the mask structure 50 may be simplified.

According to example embodiments of the present inventive concept, the EUVL mask structure may include the blind layer for shielding light at the peripheral area of the substrate. As such, light of the photolithography process may have minimized effect on a double exposure area, thereby reducing a CD variation at the point of the double exposure and increasing the transcription quality. Therefore, the EUVL process may be sufficiently applied to a mass manufacturing process for semiconductor devices. In addition, since the blind layer may be formed by the lift-off process, damage to the capping layer may be prevented or substantially reduced during the formation process for the blind layer and the formation process for the mask structure may be simplified, e.g., as compared with dry etching processes in a conventional formation process of the EUVL mask structure. The EUVL mask structure of which the capping layer rarely damaged may sufficiently decrease process failures in the photolithography process.

In contrast, while a conventional EUVL mask structure, i.e., without the blind layer, may have a reduced thickness of the absorption pattern to avoid a shadow effect, the reduced thickness may cause a double exposure in an absorption pattern of a neighboring shot around a peripheral portion of the mask pattern due to poor optical density. As such, the transcription quality of the conventional mask pattern may be reduced.

For example, as illustrated in an electron microscope photograph of FIG. 1, when the absorption pattern has a thickness of about 42.4 nm and the optical density (OD) is about 1.07, the transcription quality of the mask pattern decreases as the number of the double exposure increases. In the same way, when the absorption pattern has a thickness of about 52.4 nm and the optical density is about 1.35, the transcription quality of the mask pattern also decreases as the number of the double exposure increases. However, when the absorption pattern has a thickness of about 82.8 nm and the optical density is about 2.36, the transcription quality of the mask pattern is not deteriorated by the number of the double exposure. That is, according to the electron microscopic picture in FIG. 1, while good transcription quality of the conventional mask pattern under double exposure may be achieved with a high thickness of the absorption pattern, such high thickness may frequently cause a shadow effect on the mask pattern.

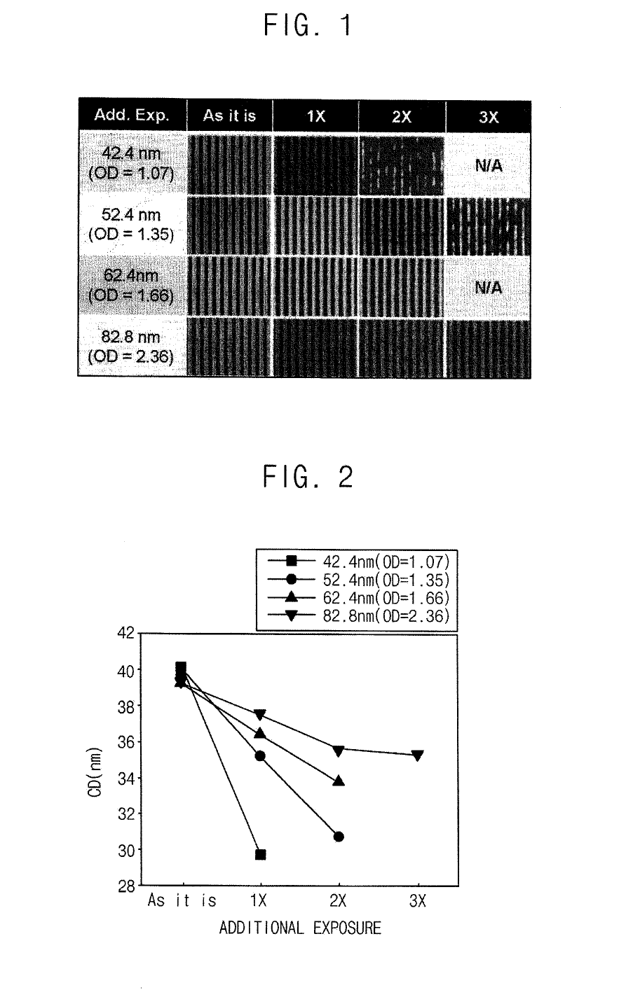

In another example, as illustrated in FIG. 2, repeated double exposure may cause reduction of CD in accordance with the thickness of the absorption pattern and the OD. Therefore, double exposure may occur between neighboring shots in a photolithography process when using a conventional mask pattern, thereby causing non-uniform CD.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

1. A method of forming a mask structure for an extreme ultraviolet ray lithography (EUVL) process, comprising:
defining a substrate including a first area and a second area, such that the first area has a pattern structure configured to selectively transmit light for the EUVL process and the second area encloses the first area;
forming a reflection layer on the substrate, the reflection layer including alternately stacked molybdenum layers and silicon layers on the substrate;
forming a capping layer on the reflection layer;
forming an absorption pattern on the capping layer, the absorption pattern including a central portion corresponding to the first area of the substrate and a peripheral portion corresponding to the second area of the substrate; and
forming a blind layer on the peripheral portion of the absorption pattern.

2. The method as claimed in claim 1, wherein forming the capping layer includes forming at least one of a ruthenium layer and a silicon layer.

3. The method as claimed in claim 1, wherein forming the absorption pattern includes forming a low reflectivity tantalum boron nitride layer or a tantalum nitride layer.

4. The method as claimed in claim 1, further comprising:
forming a photosensitive pattern on the central portion of the absorption pattern;
forming the blind layer on the photosensitive pattern and the peripheral portion of the absorption pattern; and
sequentially removing the blind layer and the photosensitive pattern from the first area of the substrate, such that the blind layer remains only on the peripheral portion of the absorption pattern.

5. The method as claimed in claim 4, wherein forming the blind layer includes:
pre-cleaning the peripheral portion of the absorption pattern by an ion beam etching process; and
depositing a light-shielding material onto surfaces of the photosensitive pattern and the peripheral portion of the absorption pattern by an ion beam deposition process.

6. The method as claimed in claim 5, wherein depositing the light-shielding material includes depositing at least one of chromium, tantalum nitride, and tantalum boron nitride.

7. The method as claimed in claim 5, wherein pre-cleaning and depositing steps are performed in-situ with each other in a same process chamber.

8. The method as claimed in claim 5, wherein the ion beam etching process for the pre-cleaning is performed by ion beams of oxygen gas, argon gas, and/or nitrogen gas.

9. The method as claimed in claim 1, wherein removing the blind layer and the photosensitive pattern is performed by a lift-off process.

10. A method of forming a mask structure for an extreme ultraviolet ray lithography (EUVL) process, comprising:
forming a reflection layer on a substrate, the substrate including a first area having a pattern structure configured to selectively transmit light for the EUVL process and a second area enclosing the first area;
forming a capping layer on the reflection layer;
forming an absorption pattern on the capping layer, the absorption pattern including:
a central portion corresponding to the first area of the substrate, the central portion including a gap space partially exposing the capping layer in the first area of the substrate, and
a peripheral portion corresponding to the second area of the substrate and covering the capping layer in the second area of the substrate;
forming a sacrificial pattern filling the gap space of the central portion of the absorption pattern;
forming a blind layer on the sacrificial pattern and the absorption pattern;
partially removing the blind layer from the first area of the substrate, such that the central portion of the absorption pattern and the sacrificial pattern are exposed; and
removing the sacrificial pattern from the first area of the substrate, such that the blind layer remains on the peripheral portion of the absorption pattern.

11. The method as claimed in claim 10, wherein forming the reflection layer includes alternately stacking molybdenum layers and silicon layers on the substrate.

12. The method as claimed in claim 10, wherein forming the capping layer includes forming at least one of a ruthenium layer and a silicon layer.

13. The method as claimed in claim 10, wherein forming the absorption pattern includes forming a low reflectivity tantalum boron nitride layer or a tantalum nitride layer.

14. The method as claimed in claim 10, wherein forming the sacrificial pattern includes forming at least one of a photosensitive pattern, a polysilicon pattern, and an oxide pattern.

15. The method as claimed in claim 10, wherein forming the blind layer includes using a light-shielding material, the light-shielding material including at least one of chromium, tantalum nitride, and tantalum boron nitride.

16. The method as claimed in claim 10, wherein removing the blind layer is performed by a dry etching process, and removing the sacrificial pattern is performed by a wet etching process.

17-20. (canceled)
